(19) United States
(12) Patent Application Publication
(10) Pub. No.: US 2019/0182954 A1
(43) Pub. Date: Jun. 13, 2019

(54) MEMORY CARD PIN LAYOUT FOR AVOIDING CONFLICT IN COMBO CARD CONNECTOR SLOT

(71) Applicant: Western Digital Technologies, Inc., San Jose, CA (US)

(72) Inventors: Shajith Musaliar Sirajudeen, Bengaluru (IN); Krishnamurthy Dhakshinamurthy, Bangalore (IN); Taninder Singh Sijher, Bangalore (IN); D. Jegathese, Tuticorin (IN); Yosi Pinto, Tel Aviv (IL); Warren Middlekauff, San Jose, CA (US)

(73) Assignee: Western Digital Technologies, Inc., San Jose, CA (US)

(21) Appl. No.: 15/923,376

(22) Filed: Mar. 16, 2018

(30) Foreign Application Priority Data
Dec. 8, 2017 (IN) 201741044076

(51) Int. Cl. H05K 1/11; H05K 7/10; H05K 5/02; H01R 12/71; G06K 19/077; G06F 13/42

(52) U.S. Cl. CPC H05K 1/117; H05K 7/1084; H05K 5/0291; H01R 12/714; G06K 19/07743; G06F 2213/0026; H05K 2201/09409; H05K 2201/094; H05K 2201/09445; H05K 2201/10159; G06F 13/4282

(57) ABSTRACT

A μSD card is disclosed including an arrangement of interface pins enabling the μSD card to be used in a combination connector having a slot configured to receive both μSD cards and SIM cards. In examples, the μSD card may include multiple rows and/or columns of interface pins configured at positions such that, when the μSD card is inserted into a multi-card connector, the positions of the μSD card interface pins do not overlap with the positions of SIM card contacts in the connector.

### BACKGROUND

MicroSD (μSD) cards are a known and commonly used flash memory standard. FIG. 1 shows an example of a conventional μSD card 50 including a single row interface pins. The μSD card 50 may for example be a UHS (ultra-high speed) I μSD card 50 having an eight pin interface including power, ground, clock, command and four data lines, but other types of μSD cards are known including a single row of interface pins. It is also known to provide μSD cards with a second row of interface pins, such as for example the μSD card 60 shown in prior art FIG. 2. The μSD card 60 may for example be a conventional UHS-II μSD card 60 having an additional row of pins including additional data lines to support the ultra-fast UHS-II bus interface but other types of cards with similar shape as μSD are known including additional row of interface pins. The μSD card 60 may be backward compatible with the legacy μSD card 50, so that the μSD card 60 can be used in cards slots configured for the legacy μSD card 50, albeit at slower speeds.

For mobile devices such as smartphones, there is a growing demand to use multiple type of cards on a single device, such as for example a mixture of an μSD card and a SIM card. Connectors are being developed which have a slot which can accept either a μSD card or SIM card. For example, Japan Aviation Electronics Industry, Ltd. (JAE) has developed a compact combo 3-in-2 type card connector. The ST19 Series combo 3-in-2 type card connector is a push-eject type card connector that is compatible with two patterns of card installation. It can accept two nano-SIM cards or a combination of one nano-SIM card and one μSD card.

FIG. 3 shows a cross-sectional top view of a conventional combination 3-in-2 type card connector 70 within a slot 72 in a host device 74 for receiving a tray 76. The combination card connector 70 in slot 72 may comprise a number of electrical contacts 78. In particular, a first set of contacts 78a are provided in a first area 80, and are configured to mate with a SIM card, such as conventional nano-SIM card 82 shown in FIG. 4. SIM card 82 is shown with eight pins (C4 and C8 are not used in connector 70), but may alternatively include six pins. A second set of contacts 78b and 78c are provided in a second, combo area 84. The contacts 78b in combo area 84 are configured to mate with a μSD card, such as a conventional legacy μSD card 50 shown in FIG. 1. The contacts 78c in combo area 84 are configured to mate with a second SIM card, such as conventional nano-SIM card 82 shown in FIG. 4. The SIM contacts 78c are labeled C1-C7 in FIG. 3. The combination connector 70 is configured to receive the tray 76 which includes a first opening 88 configured to hold a first SIM card 82, and a second opening 90 configured to hold either one of a μSD card 50 or a second SIM card 82.

There is a desire to use a μSD card 60 including multiple rows of interface pins (FIG. 2) in a connector, such as in the opening 90 of the combination connector 70 shown in FIG. 3. However, the second row of interface pins on the μSD card 60 conflict with the SIM card contacts 78c in the combo area 84. For example, one or more of the interface pins in the second row of the μSD card 60 conflict with (i.e., lie in contact with) one or both of contacts C3 and C7 when a card 60 is used in the combination connector 70. For example, a conflict may exist between SIM card contact C3 and interface pins 14, 15 or 16 of μSD card 60. There may also be a conflict between SIM card contact C7 and interface pins 9 and 17 of μSD card 60. Such a conflict may damage the pins or contacts, and may prevent or adversely affect the operation of μSD card 60 in combination connector 70.

### DESCRIPTION OF THE DRAWINGS

FIGS. 1 and 2 are bottom views of conventional μSD cards including one row of interface pins and two rows of interface pins, respectively.

FIG. 3 is a prior art illustration of a conventional connector for receiving both a μSD card and a nano-SIM card.

FIG. 4 is a prior art illustration of a conventional nano-SIM card.

FIG. 5 is a bottom view of a μSD card according to an embodiment of the present technology enabling the μSD card to be used in a card slot including both μSD and nano-SIM card contacts.

FIG. 6 is an illustration of a card connector and the μSD card of FIG. 5.

FIGS. 7-12 are views of μSD cards including different arrangements of interface pins according to different embodiments of the present technology.

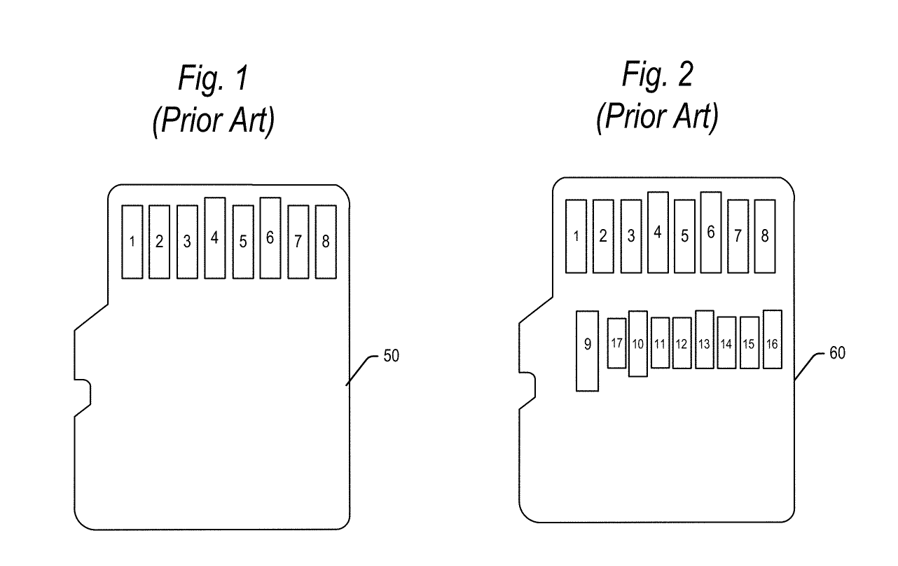

### DETAILED DESCRIPTION

The present technology will now be described with reference to the figures, which in embodiments, relate to a μSD card including an arrangement of interface pins enabling a μSD card with multiple rows of interface pins to be used in a connector having a combination slot configured to receive both legacy μSD cards and memory cards configured according to another standard, such as SIM cards. In embodiments, the μSD card of the present technology may include a first row of interface pins configured to mate with legacy μSD card contacts in a card slot. The μSD card of the present technology may further include one or more additional rows and/or columns of interface pins configured at positions such that, when the μSD card is inserted into a combination slot, the positions of the μSD card interface pins do not conflict with or overlap with the positions of SIM (or other standard) card contacts in the slot.

It is understood that the present invention may be embodied in many different forms and should not be construed as being limited to the embodiments set forth herein. Rather, these embodiments are provided so that this disclosure will be thorough and complete and will fully convey the invention to those skilled in the art. Indeed, the invention is intended to cover alternatives, modifications and equivalents of these embodiments, which are included within the scope and spirit of the invention as defined by the appended claims. Furthermore, in the following detailed description of the present invention, numerous specific details are set forth in order to provide a thorough understanding of the present invention. However, it will be clear to those of ordinary skill in the art that the present invention may be practiced without such specific details.

The terms “top”/“bottom,” “upper”/“lower” and “vertical”/“horizontal,” and forms thereof, as may be used herein are by way of example and illustrative purposes only, and are not meant to limit the description of the technology inasmuch as the referenced item can be exchanged in position and orientation. Also, as used herein, the terms “substantially” and/or “about” mean that the specified dimension or parameter may be varied within an acceptable manufacturing tolerance for a given application. In one embodiment, the acceptable manufacturing tolerance is ±0.25% of a defined component dimension.

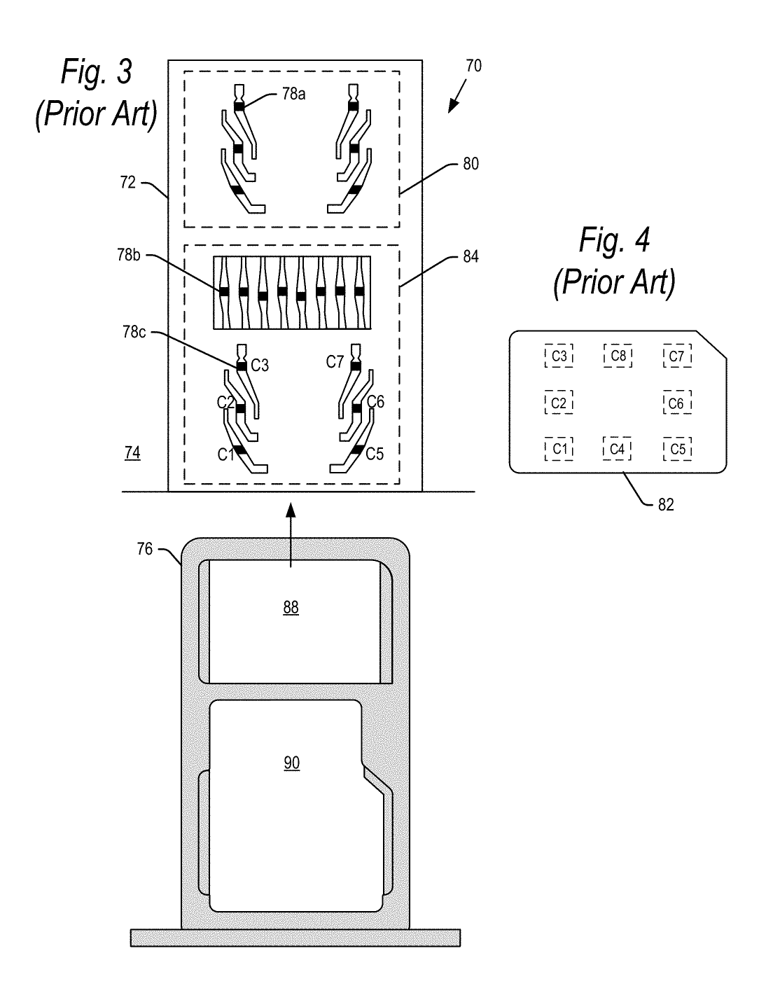

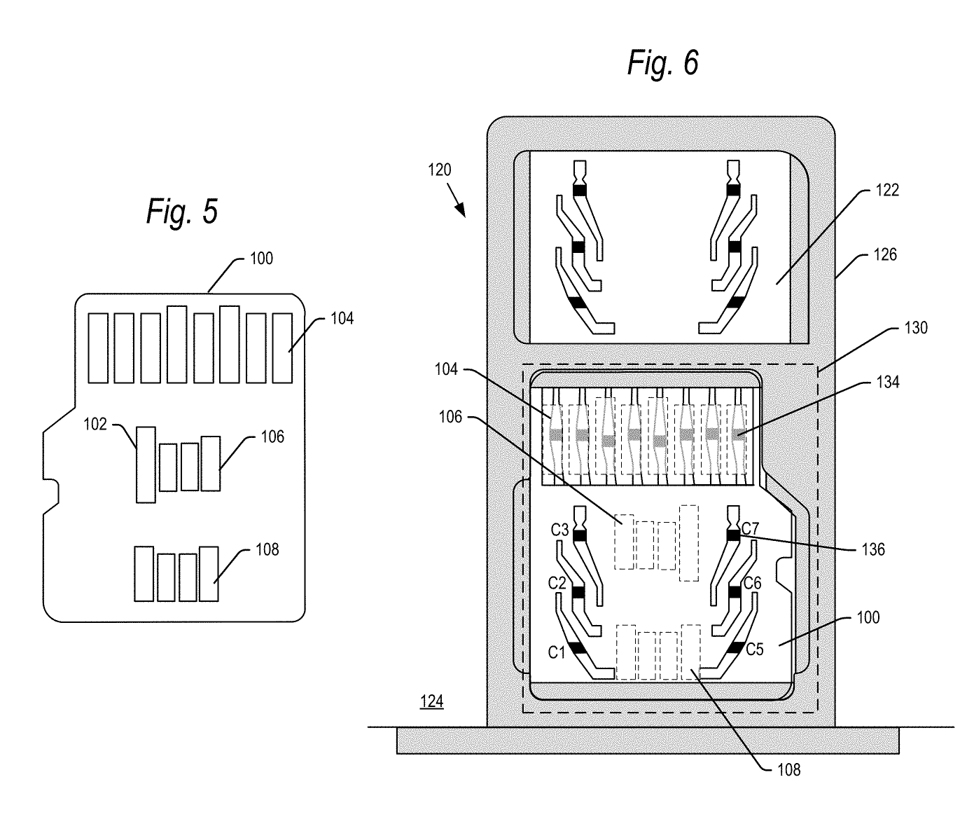

Referring now to FIG. 5, there is shown a OD card 100 including a plurality of interface pins 102 including multiple rows of interface pins 102. In one embodiment, the μSD card 100 is configured to operate according to the PCI-Express™ (PCIe) expansion bus standard adapted into a μSD card form factor. However, it is understood that the μSD card 100 may be configured according to any of a variety of other standard and non-standard bus protocols which include interface pins in addition to a single row of legacy interface pins. As one further example, the μSD card 100 may be configured to operate according to the UHS-II standard. In another example, the card 100 may be configured as a Universal Flash Storage (UFS) card, which has a very similar shape to a μSD card, including multiple rows of interface pins that may be inserted in a connector, such as in the opening 90 of the combination connector 70 shown in FIG. 3 and may be configured to operate according to the UFS specification.

The embodiment shown in FIG. 5 includes a first row 104 of legacy interface pins 102, conforming in number and position to interface pins provided for example on a UHS-I μSD card having a single row of interface pins. The first row 104 may include interface pins conforming in number and/or position to interface pins of a memory card standard other than UHS-I in further embodiments.

The embodiment of the μSD card 100 in FIG. 5 further includes a second row 106 and a third row 108 of interface pins 102. In FIG. 5 and the embodiments explained below, interface pins 102 in μSD card 100 in rows or columns other than row 104 of legacy interface pins may be referred to as non-legacy interface pins 102.

The illustrated embodiment of FIG. 5 includes four vertically oriented non-legacy interface pins 102 in the second row 106, and four vertically oriented non-legacy interface pins 102 in the third row 108. It is understood that the number and size of the interface pins 102 in rows 106 and 108 may vary in further embodiments, based for example in part on functionality of the respective pins 102. The vertical position (i.e., along the length dimension of the μSD card 100) of the pins 102 in the rows 106 and/or 108 may vary from that shown in FIG. 5 in further embodiments.

In embodiments, the three rows 104, 106 and 108 provide sixteen interface pins 102 supporting power, ground and signal transfer of both, SD and PCIe bus standard. However, there may be more or less pins than that in further embodiments. In one further example explained below with respect to FIGS. 11 and 12, there may be seventeen or eighteen interface pins 102, in multiple rows such as for example three rows, which together are configured to operate according to the SD and PCIe bus standard.

As noted, the interface pins may be configured to operate according to other bus standards in further embodiments. In one such further embodiment, the μSD card 100 may operate according to the UHS-II μSD standard, with the pins 102 in the row 104 conforming in size and functionality to the size and functionality of the interface pins in the first row of a conventional UHS-II μSD card. The interface pins in the rows 106 and 108 may likewise conform to the size and functionality of the interface pins in the second row of a conventional UHS-II μSD card.

FIG. 6 is a cross-sectional top view of a combination card connector 120 for accepting flash memory cards of different configurations. In one example, the card connector 120 may be the ST19 Series 3-in-2 card connector from JAE described above, mounted within a slot 122 of a host device 124. The card connector 120 is shown with an inserted tray 126 including the μSD card 100 of FIG. 5 as explained below. The combination card connector 120 may be used in any of a variety of host devices 124, including for example mobile smart phones, tablets, laptops, desktops, gaming devices, automotive devices, servers and other mobile or stationary systems.

As noted, the card connector 120 may be a ST19 Series 3-in-2 card connector where the connector 120 is configured to receive either a pair of nano-SIM cards, or a μSD card and a nano-SIM card. In particular, the connector 120 includes a combo area 130 having a first group of contacts 134 configured to mate with the legacy interface pins 102 in the first row 104 of a μSD card 100. The combo area 130 further includes a second group of contacts 136 configured to mate with the interface pins on a standard nano-SIM card. The contacts 136 are numbers C1 to C7 in FIG. 6. The contacts C1 to C7 may be affixed within slot 122 by a frame (not shown) mounted to the card connector 120.

In FIG. 6, μSD card 100 of FIG. 5 has been flipped over and inserted into the tray 126 of the combination connector 120, and the tray 126 is shown in FIG. 6 inserted into the slot 122 of the combination connector 120. As set forth in the Background section, if the interface pins 102 shown in the second and third rows 106, 108 were instead included in a single, second row as in the UHS-II μSD card 60 (prior art FIG. 2), certain pins in the second row would conflict with certain contacts 136 provided for the nano-SIM card. For example, a conflict may exist between SIM card contact C3 and interface pins 14, 15 or 16, and/or between SIM card contact C7 and interface pins 9 and 17. A conflict as used herein refers to an overlap between a μSD card interface pin and a nano-SIM card contact resulting in electrical connection between the interface pin and the nano-SIM card contact.

However, in accordance with aspects of the present technology, by arranging the interface pins 102 into multiple rows, such as rows 106 and 108, conflict between the μSD interface pins 102 and the nano-SIM card contacts is avoided. As shown in FIG. 6, the legacy interface pins 102 in row 104 align with their proper respective μSD contacts 134. Additionally, none of the interface pins in rows 106 and 108 conflict with any of the SIM contacts 136. That is, there is no overlap between the interface pins in rows 106 and 108 with any of the SIM contacts 136.

Thus, the μSD card 100 of FIG. 5 may operate within the connector 120 using the legacy interface pins 102 in row 104 according to legacy data transfer standards. As explained below, the slot 120 may alternatively be configured with μSD contacts that mate not only with the legacy interface pins, but also μSD contacts provided to mate with the non-legacy interface pins 102 of rows 106 and 108. In such an embodiment, data may be transferred to/from the μSD card 100 at the enhanced data transfer rates of, for example, the PCIe, UHS-II and/or UFS bus standards.

When operating within the ST19 Series combination 3-in-2 card connector 120 from JAE, it is understood that the non-legacy interface pins 102 of μSD card 100 may be arranged in a variety of different configurations that have no conflict with the SIM contacts C1 to C7, some of which are explained below. Additionally, it is understood that the non-legacy interface pins of μSD card 100 may be arranged in a wide variety of configurations to avoid contact with the non-OD card contacts in combination connectors configured to a wide variety of other standards. In such other combination connectors, the second standard may be a SIM or other standard.

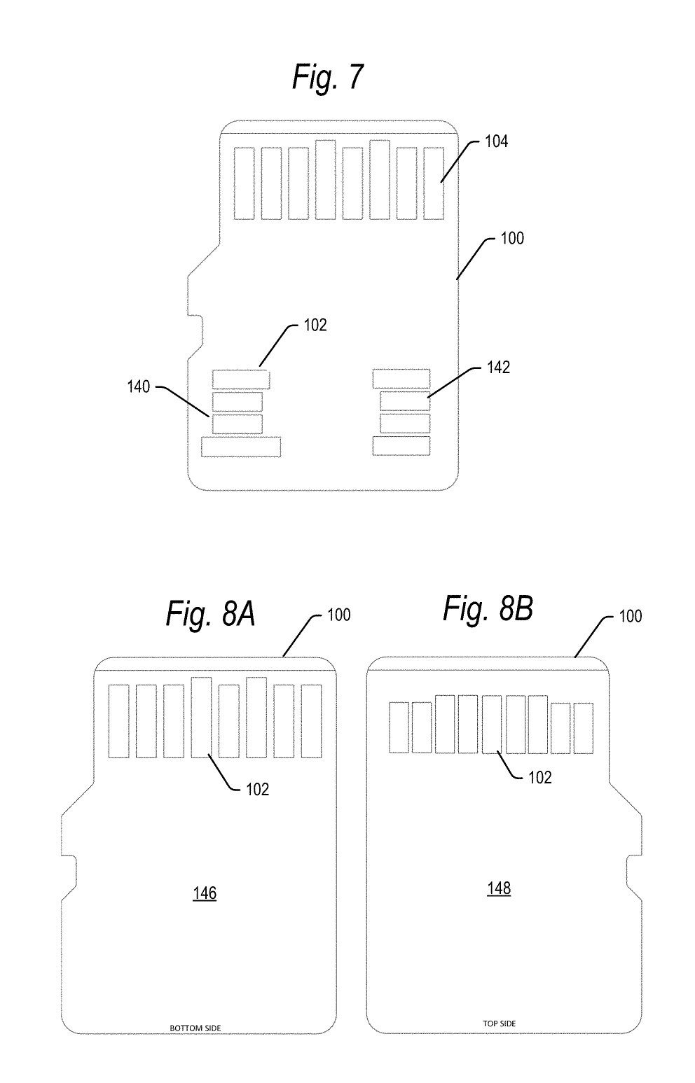

FIGS. 7-12 show further examples of μSD card 100 including interface pins 102 arranged vertically (along the length dimension of card 100) and/or horizontally (along the width dimension of card 100) which can be used within the combination connector 120 (or some other combination connector) without conflict between the interface pins 102 and the non-OD contacts in the combination connector.

FIG. 7 shows a row 104 of legacy interface pins 102, and columns 140 and 142 of non-legacy interface pins 102 at bottom left and right corners of μSD card 100. Such a configuration of interface pins may operate in a combination connector 120 having no non-μSD contacts in the lower corners of the connector, thus avoiding conflict the non-legacy interface pins 122 and any non-μSD contacts. Alternatively, the configuration of interface pins shown in FIG. 7 may operate in a combination slot 120 having no non-OD contacts in only one of the lower corners of the slot. In such an alternative embodiment, a conflict may exist in the opposite corner, which conflict may be resolved by design (such as by default disconnection of any conflicting μSD interface pins, and connecting such pins only when needed). This feature is explained below.

The illustrated embodiment of FIG. 7 includes four horizontally oriented non-legacy interface pins 102 in the column 140, and four horizontally oriented non-legacy interface pins 102 in the column 142. It is understood the number and functionality of the interface pins 102 in columns 140 and 142 may vary in further embodiments, based for example in part on functionality of the respective pins 102. The vertical position (i.e., along the length dimension of the μSD card 100) of the pins 102 in the column 140 and/or 142 may vary from that shown in FIG. 7 in further embodiments. It is also contemplated that the non-legacy interface pins 102 in the lower corners be oriented vertically, instead of horizontally as shown FIG. 7.

In embodiments, the row 104 and columns 106 and 108 provide sixteen interface pins 102 supporting power, ground and signal transfer according to the SD and PCIe bus standard. However, there may be more or less pins than that in further embodiments. In one further example, there may be seventeen or eighteen interface pins 102, with eight pins in the row 104 and the remaining pins in columns 140 and 142, which together are configured to operate according to the SD and PCIe bus standard. The interface pins in row 104 and columns 140, 142 may be configured to operate according to other bus standards in further embodiments, including for example the UHS-II μSD standard.

FIGS. 8A and 8B show interface pins 102 on a back and front surface, respectively, of μSD card 100 according to a further embodiment of the present technology. In particular, a back surface 146 shown in FIG. 8A may include the legacy interface pins 102, and a front surface 148 shown in FIG. 8B may include the non-legacy pins 102. The surfaces which have the legacy and non-legacy pins 102 may be switched in further embodiments.

In embodiments, the interface pins 102 on surfaces 146 and 148 provide sixteen interface pins 102 supporting power, ground and signal transfer according to the SD and PCIe bus standard. However, there may be more or less pins than that in further embodiments. In one further example, there may be seventeen or eighteen interface pins 102, with eight pins on surface 146 and the remaining pins on surface 148, which together are configured to operate according to the SD and PCIe bus standard. The interface pins on surfaces 146 and 148 may be configured to operate according to other bus standards in further embodiments, including for example the UHS-II μSD standard.

The μSD card 100 of FIGS. 8A and 8B may operate within the connector 120 shown in FIG. 6 using the legacy interface pins 102 on back surface 146 according to legacy data transfer standards. The non-legacy interface pins 102 on front surface 148 have no conflict with any non-OD contacts. In an alternative embodiment, the μSD card 100 of FIGS. 8A and 8B may be used in a connector slot that may have the legacy μSD contacts on a first surface of the slot (as in FIG. 6) for mating with the legacy interface pins 102 on back surface 146. The connector slot in this alternative embodiment may further include non-legacy μSD contacts on a second surface of the slot, opposed to the first surface, for mating with the non-legacy interface pins 102 on front surface 148. In such an embodiment, data may be transferred to/from the μSD card 100 at the enhanced data transfer rates of, for example, the PCIe, UHS-II or other standards.

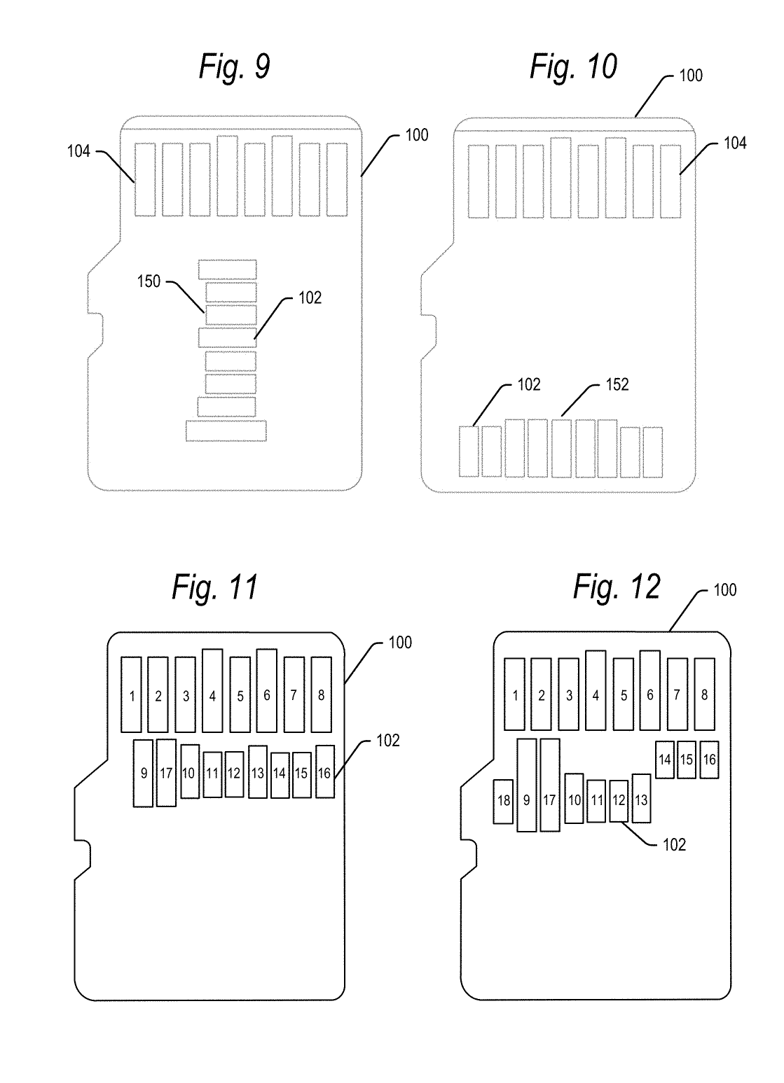

FIG. 9 shows a μSD card 100 including a row 104 of legacy interface contacts 102 as described above. The embodiment of FIG. 9 further includes a single column 150 of horizontally oriented interface pins 102. It is understood the number and functionality of the interface pins 102 in column 150 may vary in further embodiments, based for example in part on functionality of the respective pins 102. The vertical position (i.e., along the length dimension of the μSD card 100) of the pins 102 in the column 150 may vary from that shown in FIG. 9 in further embodiments.

In embodiments, the row 104 and columns 150 provide sixteen interface pins 102 supporting power, ground and signal transfer according to the SD and PCIe bus standard. However, there may be more or less pins than that in further embodiments. In one further example, there may be seventeen or eighteen interface pins 102, with eight pins 102 in row 104 and the remaining interface pins in column 150, which together are configured to operate according to the SD and PCIe bus standard. The interface pins in row 104 and column 150 may be configured to operate according to other bus standards in further embodiments, including for example the UHS-II μSD standard.

FIG. 10 shows a μSD card 100 including a row 104 of legacy interface contacts 102 as described above. The embodiment of FIG. 10 further includes a single row 152 of vertically oriented interface pins 102. It is understood the number and functionality of the interface pins 102 in row 152 may vary in further embodiments, based for example in part on functionality of the respective pins 102. The vertical position of the pins 102 in the row 152 may vary from that shown in FIG. 10 in further embodiments.

In embodiments, the rows 104 and 152 provide seventeen interface pins 102 supporting power, ground and signal transfer according to the SD and PCIe bus standard. However, there may be more or less pins than that in further embodiments. In one further example, there may be sixteen or eighteen interface pins 102, with eight pins 102 in row 104 and the remaining interface pins in row 152, which together are configured to operate according to the SD and PCIe bus standard. The interface pins in rows 104 and 152 may be configured to operate according to other bus standards in further embodiments, including for example the UHS-II μSD standard.

In embodiments described above, the non-legacy interface pins 102 of μSD card 100 may avoid all conflict with the non-OD contacts. That is, the non-legacy interface pins 102 of μSD card 100 may be located at positions which do not overlap with any non-μSD contacts when the μSD card 100 is inserted into the slot.

However, in further embodiments, a first group of non-legacy interface pins 102 may avoid conflict with the non-OD contacts, while a second group of interface pins 102 may overlap non-OD contacts, but the conflict of the second group is managed by design. Such design may for example entail a default disconnection of the internal circuit to the second group of interface pins, and connecting them only when they are needed. In this regard, a conflict of some interface pins may not be resolvable by design (e.g., they need to be connected in their default state). Such interface pins need to avoid conflict by selective positioning of those interface pins away from non-OD contacts.

Two examples of this further embodiment will now be explained with reference to FIGS. 11 and 12. In FIGS. 11 and 12, the μSD card 100 may include interface pins 1-8 in the first row, and 9-17 in the second row (9-18 in second row of FIG. 12). These interface pins 102 may be configured to operate according to the PCIe, UHS-II μSD or other bus standard, but the size and vertical position of the interface pins are configured to, at least in part, avoid conflict with non μSD contacts in a combo connector such as that shown in FIG. 6. For example, as noted above, when a conventional multi-row μSD card is used in a ST19 Series 3-in-2 card connector from JAE, a conflict may exist between μSD interface pins 9 and 17 and nano-SIM contact C3 (FIG. 6). A conflict may also exist between μSD interface pins 14, 15 or 16 and nano-SIM contact C7.

The μSD interface pins 14 and 15 may typically be RX−/RX+ of PCIe, which is the output of differential interface that is expected to operate in high bit rates such as 8 Gb/s. Therefore, it would be difficult to protect this pins without degradation of their performance. The μSD interface pin 16 is typically VSS (ground), which might short the nano-SIM contact C7 which is CLK output signal of the SIM. Accordingly, conflict with these pins is avoided by making these pins smaller in length and/or moving these pins nearer to the first row (or elsewhere on the μSD card), as shown in FIGS. 11 and 12, to avoid conflict with the nano-SIM contact C7.

In contrast, the μSD interface pins 9 and 17 may typically be used as either power supply or single ended input output signal lines. These pins are less critical, and, to the extent a conflict may exist with nano-SIM contact C3, the conflict can be resolved by design, such as default disconnection, and connecting them when needed.

The solution of FIGS. 11 and 12 for example provides a simple solution that eliminates conflicts for certain interface pins (14, 15 and 16), while keeping the rest of the contacts of existing connectors in the same horizontal position. By keeping the same horizontal position, the same contact path is kept in push-pull and push-push type of connectors used for such cards in the market. Such a solution minimizes effort in feasibility study, standardization and implementation.

The solution of FIG. 12 for example provides a simple solution that eliminates conflicts for certain interface pins (14, 15 and 16), while keeping the rest of the contacts of existing connectors in the same position as of existing SD UHS-II card. Such a solution further minimizes effort in feasibility study, standardization and implementation.

The examples set forth in FIGS. 5 and 7-12 are not intended to be exhaustive of all possible positions for the non-legacy interface pins 102. It is understood that the non-legacy interface pins may be provided in a wide variety of other configurations to avoid conflict with SIM contacts in a ST19 Series 3-in-2 card connector from JAE.

It is also understood that the present technology is not limited only to repositioning of non-legacy interface pins 102 to avoid conflict with the host contacts of a ST19 Series 3-in-2 card connector from JAE. The present technology may reposition non-legacy interface pins 102 in a wide variety of other locations to avoid conflict with the host contacts of any of a wide variety of other combination card connectors in further embodiments, some of which are shown in the figures.

In summary, the present technology relates to a microSD (μSD) card configured for insertion in a combo slot comprising μSD and non-μSD contacts, the μSD card comprising: a first group of interface pins configured to mate with the μSD contacts upon insertion of the μSD card into the combo slot; and a second group of one or more interface pins whose positions are configured to avoid contact with the non-μSD contacts in the combo slot upon insertion of the μSD card into the combo slot.

In another example, the present technology relates to a microSD (OD) card, comprising: a first group of interface pins configured to mate with μSD contacts upon insertion of the μSD card into a ST19 Series 3-in-2 card connector of the host device; and a second group of one or more interface pins whose positions have been configured to avoid contact with nano-SIM contacts upon insertion of the μSD card into a ST19 Series 3-in-2 card connector of the host device.

The foregoing detailed description of the invention has been presented for purposes of illustration and description. It is not intended to be exhaustive or to limit the invention to the precise form disclosed. Many modifications and variations are possible in light of the above teaching. The described embodiments were chosen in order to best explain the principles of the invention and its practical application to thereby enable others skilled in the art to best utilize the invention in various embodiments and with various modifications as are suited to the particular use contemplated. It is intended that the scope of the invention be defined by the claims appended hereto.

We claim:

1. A microSD (OD) card configured for insertion in a combo slot comprising μSD and non-μSD contacts, the μSD card comprising:
a first group of interface pins configured to mate with the μSD contacts upon insertion of the μSD card into the combo slot; and
a second group of one or more interface pins whose positions are configured to avoid contact with the non-μSD contacts in the combo slot upon insertion of the μSD card into the combo slot.

2. A μSD card as recited in claim 1, wherein the first and second groups of interface pins are configured to operate according to the PCIe bus standard.

3. A μSD card as recited in claim 1, wherein the first and second groups of interface pins are configured to operate according to the SD bus standard.

4. A μSD card as recited in claim 1, the first group of interface pins are in positions corresponding to positions of interface pins on μSD cards including a single row of interface pins.

5. A μSD card as recited in claim 3, wherein the second group of one or more interface pins comprise a plurality of interface pins arranged in two or more rows, the interface pins in the two more rows having a length parallel to a length of the interface pins in the first group of interface pins.

6. A μSD card as recited in claim 3, wherein the second group of one or more interface pins comprise a plurality of interface pins arranged in one or more columns, the interface pins in the one more columns having a length orthogonal to a length of the interface pins in the first group of interface pins.

7. A μSD card as recited in claim 1, further comprising a third group of one or more interface pins whose positions contact the non-OD contacts upon insertion of the μSD card into the combo slot, wherein conflict of the third group of one or more interface pins with the non-OD contacts is mitigated by design.

8. A μSD card as recited in claim 1, wherein the second group of one or more interface pins comprise a plurality of interface pins arranged in two or more rows, the interface pins in the two more rows being centrally positioned in the same horizontal position as existing second row of pins in a UHS-II μSD card.

9. A microSD (OD) card, comprising:
a first group of interface pins configured to mate with μSD contacts upon insertion of the μSD card into a ST19 Series 3-in-2 card connector of the host device; and
a second group of one or more interface pins whose positions have been configured to avoid contact with nano-SIM contacts upon insertion of the μSD card into a ST19 Series 3-in-2 card connector of the host device.

10. A μSD card as recited in claim 9, wherein the first and second groups of interface pins are configured to operate according to the SD and PCIe bus standard.

11. A μSD card as recited in claim 10, wherein the first group of interface pins comprise a row of eight interface pins, and the second group of interface pins comprise between eight and ten interface pins.

12. A μSD card as recited in claim 11, wherein the first group of interface pins are positioned a row of interface pins corresponding to the positions of a legacy μSD card comprising a single row of interface pins.

13. A μSD card as recited in claim 12, wherein the second group of one or more interface pins are positioned in positions other than directly beneath the row of interface pins.

14. A μSD card as recited in claim 12, wherein the second group of one or more interface pins comprise a plurality of interface pins arranged in two or more rows, the interface pins in the two more rows having a length parallel to a length of the interface pins in the first group of interface pins.

15. A μSD card as recited in claim 12, wherein the second group of one or more interface pins comprise a plurality of interface pins arranged in one or more columns, the interface pins in the one more columns having a length orthogonal to a length of the interface pins in the first group of interface pins.

16. A μSD card as recited in claim 9, wherein the second group of one or more interface pins comprise a plurality of interface pins arranged in two or more rows, the interface pins in the two more rows being centrally positioned in the same horizontal position as existing second row of pins in a UHS-II μSD card.

17. A μSD card as recited in claim 9, further comprising a third group of one or more interface pins whose positions contact the nano-SIM contacts upon insertion of the μSD card inserted into the ST19 Series 3-in-2 card connector of the host device, wherein conflict of the third group of one or more interface pins with the non-μSD contacts is mitigated by design.

18. A μSD card as recited in claim 17, wherein the third group of contacts is positioned in same position as a second row of interface pins in a UHS-II μSD card.
